(19) United States
(12) Patent Application Publication
(10) Pub. No.: US 2025/0060666 A1
(43) Pub. Date: Feb. 20, 2025

(54) ORGANOTIN PHOTORESIST COMPOSITION FOR PHOTOLITHOGRAPHY PATTERNING

(71) Applicant: Feng Lu, Irvine, CA (US)

(72) Inventor: Feng Lu, Irvine, CA (US)

(21) Appl. No.: 18/793,313

(22) Filed: Aug. 2, 2024

Related U.S. Application Data
(60) Provisional application No. 63/533,425, filed on Aug. 18, 2023.

(51) Int. Cl. G03F 7/004

(52) U.S. Cl. CPC G03F 7/0042

(57) ABSTRACT

An organotin photoresist composition for photolithography patterning is described, wherein organotin photoresist composition comprises a (cyclopentadienyl)tin compound, a solvent, and/or an additive. (Cyclopentadienyl)tin compound comprises cyclopentadienyl, or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

### CROSS REFERENCE TO RELATED APPLICATIONS

This application claims priority to U.S. provisional patent application No. 63/533,425 filed on Aug. 18, 2023 to Lu, entitled “Organotin photoresist composition for photolithography patterning”, of which is entirely incorporated herein by reference.

### FIELD OF INVENTION

The present invention relates to organotin photoresist composition for photolithography patterning, wherein organotin photoresist composition comprises a (cyclopentadienyl)tin compound, a solvent, and/or an additive. (Cyclopentadienyl)tin compound comprises cyclopentadienyl C₅H₅ group, or substituted cyclopentadienyl C₅H₄R, C₅H₃R₂, C₅H₂R₃, C₅HR₄, or C₅R₅ group.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist photosensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light adsorption because metals have high adsorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Among those promising advanced materials, particularly organometallic tin (organotin) compounds can provide photoresist patterning with significant advantages, such as improved resolution, photosensitivity, etch resistance, and lower line width/edge roughness without pattern collapse because of strong EUV radiation adsorption of tin, which have been demonstrated.

Organotin compounds have been demonstrated as EUV photoresists, which provide promising approach for the development of further smaller features such as <7 nm. In the present invention, organotin photoresist composition comprises a (cyclopentadienyl)tin compound, a solvent, and/or additive, wherein cyclopentadienyl includes cyclopentadienyl C₅H₅ group, or substituted cyclopentadienyl C₅H₄R, C₅H₃R₂, C₅H₂R₃, C₅HR₄, or C₅R₅ group, with improved resolution, photosensitivity, etch resistance, and lower line width/edge roughness without pattern collapse for photolithography patterning.

### SUMMARY

In a first aspect, the present invention pertains to organotin photoresist composition for photolithography patterning. The organotin photoresist composition comprises a (cyclopentadienyl)tin compound, a solvent, and/or an additive. The additive is organic molecule, including organic thiol, organic alcohol, organic amine, organic amide, organic carboxylic acid, organic phosphine, organic phosphine oxide, or organic phosphonic acid. The present invention is to provide improved resolution, photosensitivity, etch resistance, and lower line width/edge roughness without pattern collapse for photolithography patterning. In addition, (cyclopentadienyl)tin compounds also may be used as precursors for the preparation of organotin photoresists, or photoresist compositions.

Cyclopentadienyl group includes cyclopentadienyl C₅H₅ group, or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

Cyclopentadienyl group also comprises hapticity of η¹, η², η³, η⁴, or η⁵ of isomers.

In some embodiments, cyclopentadienyl comprises 1,3- or 2,4-cyclopentadienyl C₅H₅ group, or substituted 1,3 or 2,4-cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

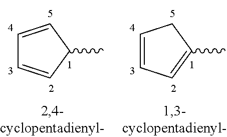

In another aspect, the invention pertains to radiation sensitive (cyclopentadienyl)tin compound photoresists, wherein (cyclopentadienyl)tin compound is one or more selected from the group of Chemical Formulas (1)-(23) as below:

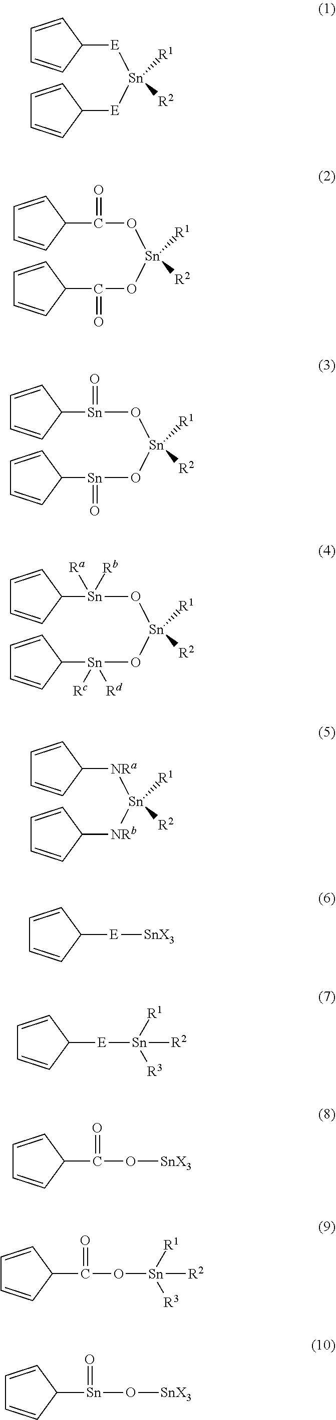

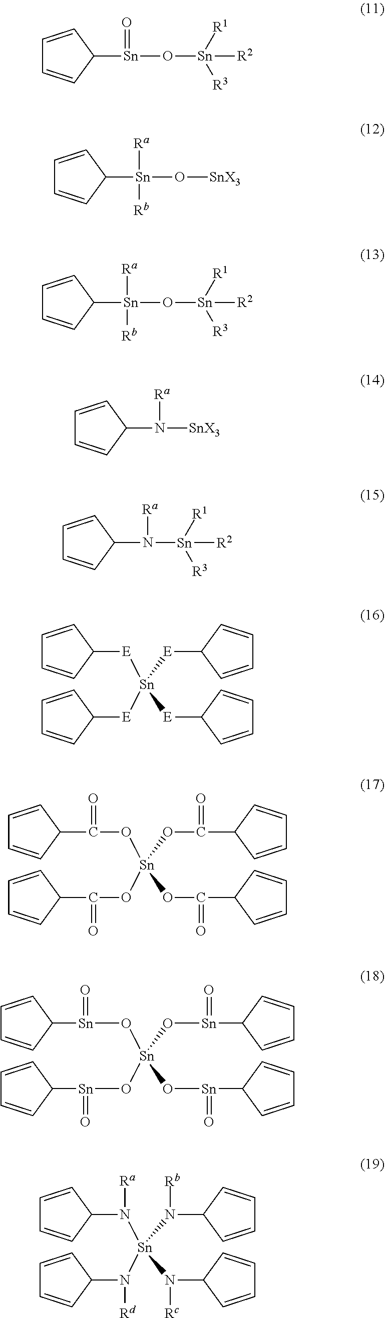

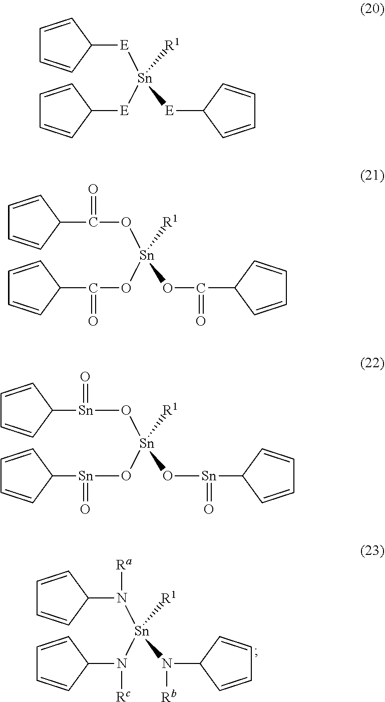

wherein R¹, R², R³ are each independently —R′, -ER′, —N(R′)₂, —O—(C═O)—R′, —(C═O)—R′, —N(R′)—(C═O)—R′, or —(C═O)—N(R′)₂, wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
wherein R^{a}, R^{b}, R^{c}, R^{d} are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te, X=F, Cl, Br, or I.

In a further aspect, the present invention pertains to a method of photolithography patterning, including depositing an organotin photoresist composition over a substrate, wherein the organotin photoresist comprises (cyclopentadienyl)tin compound; exposing the organotin photoresist layer to actinic radiation to form a latent pattern; and developing the latent pattern by applying a developer to remove unexposed or exposed portion of photoresists to form a photolithography pattern.

In other aspects, the present invention further pertains to a method of stabilization; wherein an organic additive stabilizes organotin photoresist composition for photolithography patterning. Organic additive stabilization may overcome the disadvantages like poor stability and solubility, and/or short shelf time from non-stabilized conventional organotin photoresists. The method of stabilization comprises the addition of organic additive to stabilize the as-formed organotin compounds, particularly organotin clusters, and to prevent from aggregation occurred or precipitate formation. The aggregation and precipitation can lead to scums or defects on the surface of substrates during photolithography patterning. The organic additives contain various functional groups, such as —SH, —OH, —NH₂, —COOH, —CONH₂, including but not limited to, organic thiol, organic alcohol, organic amine, organic amide, organic carboxylic acid, organic phosphine, phosphine oxide, phosphonic acid, or combinations thereof.

The present invention is to provide preparation and purification methodology of (cyclopentadienyl)tin compound photoresists with high purity for photolithography (e.g., EUV, <7 nm). The present invention is further to provide an alternative organotin (cyclopentadienyl)tin photoresists with higher resolution, sensitivity, and lower line width roughness without pattern collapse during microelectronic patterning. The sensitivity and stability of organotin compounds are important for high resolution and efficiency of photoresist for photolithography. The present invention is to provide improved stability, solubility, uniformity and shelf life of organic molecules stabilized (cyclopentadienyl)tin compound photoresist compositions for substrate surface coating without aggregation, or precipitation.

In a further aspect, the invention pertains to the methods for (cyclopentadienyl)tin photoresists deposition on a surface of semiconductor substrate by wet deposition like spin-on coating, spray coating, dip coating, vapor deposition, knife edge coating, or dry deposition like chemical vapor deposition, physical vapor deposition, atomic layer deposition, or other approaches. After exposure, the components or properties of (cyclopentadienyl)tin photoresists will change between exposed and unexposed portions. After development, the exposed or unexposed portions of (cyclopentadienyl)tin photoresist can be removed by appropriate wet or dry developer, such as organic solvent or aqueous solution. In some embodiments, the unexposed portions of (cyclopentadienyl)tin photoresists may be removed by sublimation or evaporation under high reduced pressure, and/or high temperature.

The photosensitivity, thermostability, and uniformity of organotin photoresist compositions determine high resolution and efficiency of photolithography. The (cyclopentadienyl)tin photoresists can dissolve in appropriate organic solvents to form uniformed solution composition for deposition on the surface of substrate for photolithography patterning. The organic solvents include, but not limited to, aromatic solvents, pentane, hexane, cyclohexane, tetrahydrofuran, dimethoxyethane, alcohol, ether, ester, methylene chloride, chloroform, or a combination thereof.

The invention relates to radiation sensitive (cyclopentadienyl)tin photoresist composition, which can be efficiently patterned after exposure to extreme ultraviolet radiation (EUV), deep ultraviolet radiation (DUV), electron beam radiation, X-ray radiation, or ion-beam radiation, or other likes to form high resolution patterns with low line width roughness, high resolution, low dose and large contrast, such as for <7 nm.

Furthermore, the present invention pertains to the methods for purification of (cyclopentadienyl)tin compounds. The purification methods include distillation, extraction, filtration, recrystallization, column chromatography, coordination, sublimation, or a combination thereof.

### BRIEF DESCRIPTION OF THE DRAWINGS

FIG. 1 illustrates a flowchart of organotin photoresist radiation photolithography patterning processing on the surface of semiconductor substrate surface.

### DETAILED DESCRIPTION

The present invention pertains to organotin photoresist composition for photolithography patterning, wherein organotin photoresist composition comprises a (cyclopentadienyl)tin compound, a solvent, and/or an additive. Cyclopentadienyl group includes cyclopentadienyl C₅H₅ group, or substituted cyclopentadienyl C₅H₄R, C₅H₃R₂, C₅H₂R₃, C₅HR₄, or C₅R₅ group. The present invention is to provide a method of photolithography patterning of (cyclopentadienyl)tin compound photoresist composition, particularly, suitable for EUV lithography (e.g. <7 nm). The method of photolithography patterning comprises depositing a (cyclopentadienyl)tin compound photoresist composition over a substrate to form a photoresist layer after baking, exposing the photoresist layer to actinic radiation to form a latent pattern; and developing the latent pattern by applying a developer to remove the unexposed or exposed portion of photoresists to form a photolithography pattern. The present invention is further to provide a method of stabilization of organotin photoresist by applying organic molecules as additives to stabilize (cyclopentadienyl)tin compounds, particularly clusters. Organic molecules stabilized (cyclopentadienyl)tin compound photoresists may have higher resolution, sensitivity, solubility, stability, shelf life, and lower line width roughness without pattern collapse during microelectronic patterning. The photosensitivity and thermostability of organotin photoresists determine high resolution and efficiency for photolithography patterning.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The term “alkyl” or“alkyl group” refers to a saturated linear or branched-chain substituted or unsubstituted hydrocarbon of 1 to 20 carbon atoms, e.g., methyl, ethyl, propyl, butyl. The term “alkenyl” refers to an aliphatic hydrocarbon of 2 to 20 carbon atoms containing at least one double bond. The term “alkynyl” refers to an aliphatic hydrocarbon of 2 to 20 carbon atoms containing at least one triple bond. The term “cycloalkyl” refers to cyclic aliphatic hydrocarbon of 3 to 20 carbon atoms, e.g., cyclopropyl, cyclobutyl, cyclohexyl. The term “cycloalkenyl” refers to substituted and unsubstituted cyclic aliphatic unsaturated organic groups of 3 to 20 carbon atoms including at least one double bond hydrocarbon. The term ‘aryl” refers to substituted or unsubstituted aromatic group with 6-20 carbon atoms, e.g., phenyl, benzyl.

In some embodiments, cycloalkenyl group comprises substituted and unsubstituted C4 to C8 cyclic aliphatic unsaturated organic groups including at least one double bond, for example,

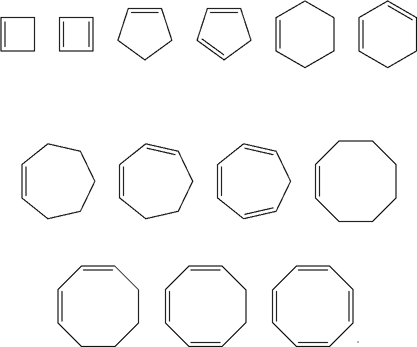

The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like.

The term “amine” refers to primary (—NH₂), secondary (—NHR), tertiary (—NR₂) amine group. The term “cyclic amine” refers to [R—NH—R′], wherein [R—R′] is cyclic substituted and unsubstituted C3 to C8 organic groups, including, but not limited to:

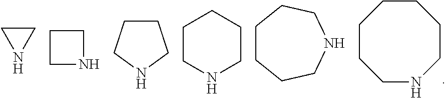

The term “ether” refers to the R—O—R′ group. The term “cyclic ether” refers to the [R—O—R′], wherein [R—R′] is cyclic substituted and unsubstituted C3 to C8 organic groups, e.g.,

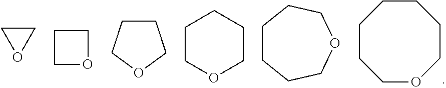

The term “ester” refers to the R—(C═O)—O—R′ group. The term “cyclic ester” refers to the [R—(C═O)—O—R′], wherein [R—R′] is cyclic substituted and unsubstituted C4 to C8 organic groups, e.g.,

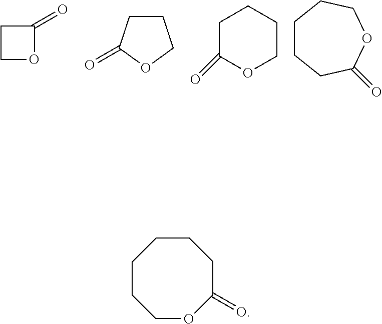

The term “halide” refers to the F, Cl, Br, or I. The term “nitro” refers to the —NO₂. The term “silyl” refers to the —SiR—, —SiR₂—, or —SiR₃ group. The term “thiol” refers to —SH group. The term “thiolate” refers to —SR group. The term “carbonyl” refers to the —C═O group. The term “oxo” refers to —O—, or ═O. In the above described, R, R′ are independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms.

In the present disclosure, the term “substituted” refers to replacement of a hydrogen atom with a C1 to C20 alkyl group, a C2 to C20 alkene group, a C2 to C20 alkyne group, a C3 to C20 cycloalkyl group, a C6 to C20 aryl group, or other relevant groups, e.g., acid, amide, amine, cyano, ether, cyclic ether, ester, cyclic ester, halide, imine, nitro, silyl, thiol, or carbonyl group, for example, chloroalkyl, fluoroalkyl, fluorobenzyl, trifluoroacetic acid.

The terms “η¹” refers to one carbon atom bonded to one metal atom. The terms “η²” refers to two carbon atoms bonded to one metal atom. The terms “η³” refers to three carbon atoms bonded to one metal atom. The terms “η⁴” refers to four carbon atoms bonded to one metal atom. The terms “η⁵” refers to five carbon atoms bonded to one metal atom.

EUV lithography is under the development for the mass production of next generation <7 nm node. EUV photoresists are required to achieve higher performance, higher sensitivity and resolution, and cost reduction.

EUV light has been applied for photolithography at about 13.5 nm. In some embodiments, the EUV light can be generated from Sn plasma or Xe plasma source excited using high energy lasers or discharge pulses.

Organometallic photoresists are used in EUV lithography because metals have high adsorption capacity of EUV radiation. Radiation sensitivity and thermal-, oxygen- and moisture-stability are important for organometallic photoresists. In some embodiments, organometallic photoresists may adsorb moisture and oxygen, which may result in decreasing stability, as well decreasing solubility in developer solutions. In addition, in some embodiments, photoresist layer may outgas volatile components prior to the radiation exposure and development operations, which may negatively affect the lithography performance, pattern collapse and increase defects.

In general, metal central plays the key role in determining the absorption of photo radiation. Tin atom provides strong absorption of extreme ultraviolet (EUV) light at 13.5 nm, therein tin cations can be selected based on the desired radiation and absorption cross section. The organic ligand bonded to tin also has absorption of EUV light. The tuning and modification of organic ligands can change the resolution, sensitivity and radiation absorption, and the desired control of the material properties.

(Cyclopentadienyl)tin compound photoresists comprise cyclopentadienyl group, Sn—C bond, or Sn—O bond, or Sn—S bond, or Sn—Se bond, or Sn—Te bond, or Sn—N bond, or Sn—X bond (X=F, Cl, Br, or I), or Sn—O—Sn bond providing desirable radiation sensitive and stabilization for precursor metal cations. The (cyclopentadienyl)tin compound photoresists possess excellent properties for the application of photolithographic patterning.

Examples of specific (cyclopentadienyl)tin compound photoresists that may be used in implementations of the invention, are represented by Chemical Formulas (1)-(23) as below:

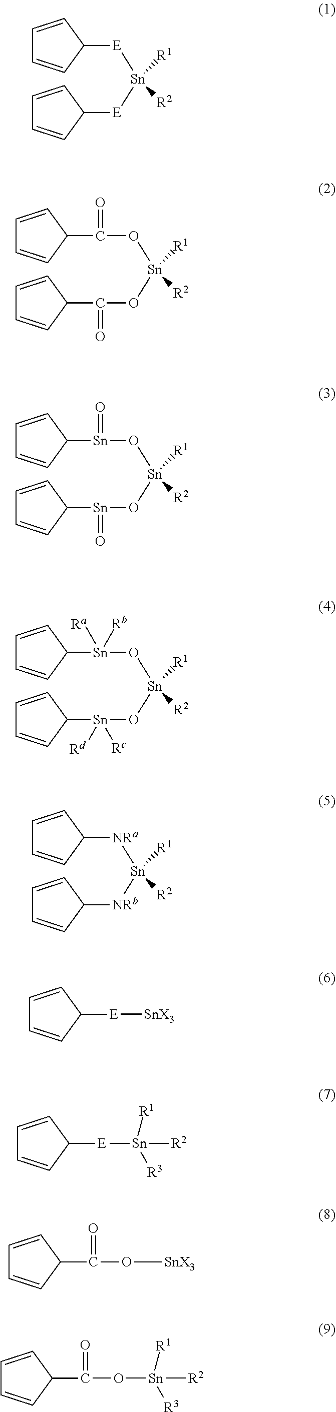

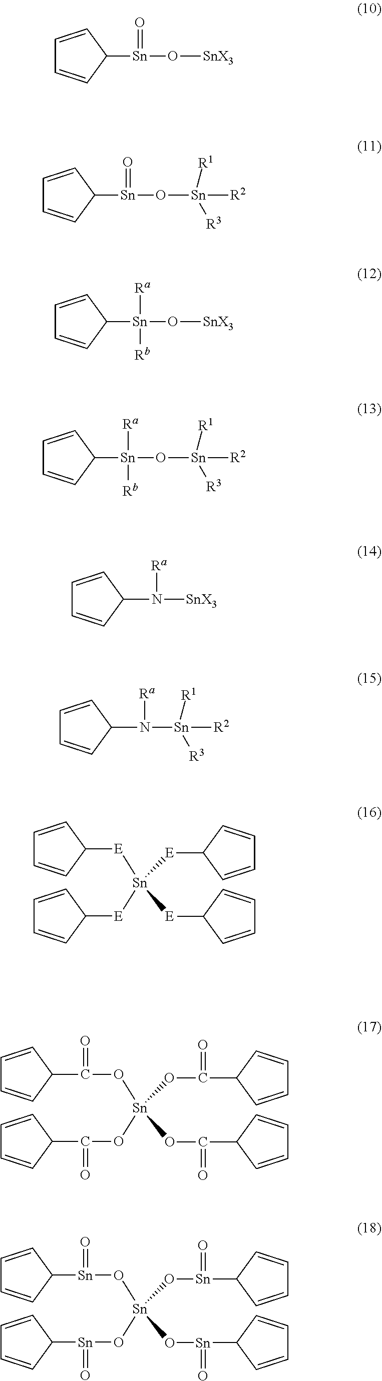

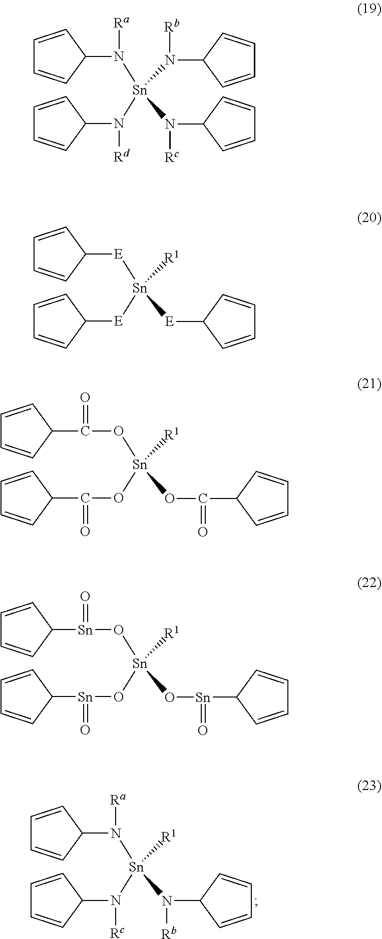

wherein R¹, R², R³ are each independently —R′, -ER′, —N(R′)₂, —O—(C═O)—R′, —(C═O)—R′, —N(R′)—(C═O)—R′, or —(C═O)—N(R′)₂, wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
wherein R^{a}, R^{b}, R^{c}, R^{d} are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te, X=F, Cl, Br, or I.

For examples, R′ is H, a methyl, ethyl, isopropyl, n-butyl, t-butyl, t-amyl, s-butyl, pentyl, hexyl, neopentyl, cyclohexyl, cyclopentyl, cyclobutyl, cyclopropyl, cyclopentadienyl, phenyl, benzyl, chlorobutyl, or fluorobenzyl group.

For examples, R¹, R², R³ are each independently cyclopentadienyl C₅H₅ group, or substituted cyclopentadienyl C₅H₄R, C₅H₃R₂, C₅H₂R₃, C₅HR₄, or C₅R₅ group hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

As one of ordinary skill in the art will recognize, the chemical compounds listed here are merely intended as illustrated examples of (cyclopentadienyl)tin compound photoresists, and are not intended to limit the embodiments to only those (cyclopentadienyl)tin compound photoresists specifically described. Rather, any suitable (cyclopentadienyl)tin compound photoresist may be used, and all such organotin compound photoresists are fully intended to be included within the scope of the present embodiments.

The (cyclopentadienyl)tin compounds represented by Chemical Formulas (1)-(23) contain cyclopentadienyl group, wherein cyclopentadienyl comprises cyclopentadienyl C₅H₅(Cp) group, or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group. For example, R is H, a methyl, ethyl, isopropyl, n-butyl, t-butyl, t-amyl, s-butyl, pentyl, hexyl, neopentyl, cyclohexyl, cyclopentyl, cyclobutyl, cyclopropyl, phenyl, or benzyl group.

In an embodiment, cyclopentadienyl is 2,4-cyclopentadienyl group, or substituted 2,4-cyclopentadienyl C₅H₄R, C₅H₃R₂, C₅H₂R₃, C₅HR₄, or C₅R₅ group. In another embodiment, cyclopentadienyl is 1,3-cyclopentadienyl group, or substituted 1,3-cyclopentadienyl C₅H₄R, C₅H₃R₂, C₅H₂R₃, C₅HR₄, or C₅R₅ group.

In some embodiments, cyclopentadienyl group, or substituted cyclopentadienyl group comprises hapticity of η¹, η², η³, η⁴, or η⁵ of isomers.

The invention pertains to methods for preparation and purification of organometallic (cyclopentadienyl)tin compounds represented by Chemical Formulas (1)-(23). All chemical manipulations, including preparation and purification, are performed under an inert atmosphere of purified nitrogen or argon in dry and degassed solvents by employing standard Schlenk techniques. The methods for purification comprise distillation, extraction, filtration, recrystallization, column chromatography, coordination, sublimation, or combinations thereof. In some embodiments, recrystallization may result in single crystals, which are suitable for X-ray diffraction analysis to determine the molecular structures. In some embodiments, column chromatography may be used to isolate and purify the as-formed (cyclopentadienyl)tin compounds.

In exemplary embodiments, (cyclopentadienyl)tin compounds represented by Chemical Formulas (1)-(23) can be synthesized from the reactions of (cyclopentadienyl)metal (C₅H₅M, M=Li, Na, or K) with appropriate reagents, such as S₈, Se powder, Te powder, CO₂, amine, Me₃SiOOSiMe₃, SnCl₄, RSnCl₃, R₂SnCl₂, or R₃SnCl with standard Schlenk techniques, where R includes, but not limited to a substituted or unsubstituted alkyl, alkenyl, alkylene, alkynyl, cycloalkyl, or cycloalkenyl group with 1 to 20 carbon atoms, or a substituted or unsubstituted aryl group with 6-20 carbon atoms.

In some embodiments, (cyclopentadienyl)metal (C₅H₅M, M=Li, Na, or K) can be prepared from freshly cracked cyclopentadiene (C₅H₆) with sodium, Na/K alloy, or strong base like methyllithium (MeLi), n-butyllithium (n-BuLi), t-butyllithium (t-BuLi). A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In an exemplary embodiment, (cyclopentadienyl)tin compounds can be prepared according to the following method:

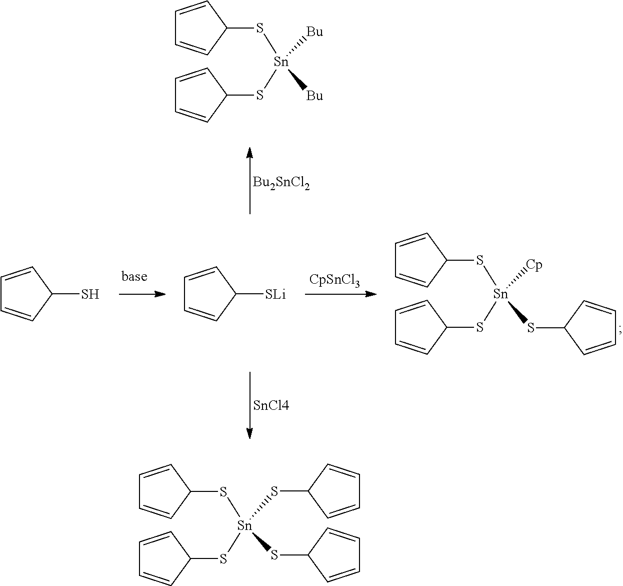

wherein the base includes, but not limited to, MeLi, n-BuLi, t-BuLi, NaBH₄, LiBEt₃H, NaH, NaOH, or KOH. In some embodiments, CpSLi or CpSNa can be synthesized through the reaction of CpLi or CpNa with elemental sulfur at ambient condition. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

Cyclopentadienyl group (C₅R₅, or Cp) may impart photosensitivity to the compounds, and the Cₚ—Sn bond formed may promote suitable solubility in an organic solvent to (cyclopentadienyl)tin compounds. Accordingly, these Cₚ—Sn bond containing (cyclopentadienyl)tin compounds according to an embodiment may have improved photosensitivity, oxygen/moisture-stability, or resolution, and may suitable for EUV photoresists, and/or as precursors for EUV lithography to form tin oxide, tin oxide hydroxide film, or similar.

The (cyclopentadienyl)tin compounds contain cyclopentadienyl-Sn bond (Cₚ—Sn bond). Cₚ—Sn bond is sensitive to UV light and occurs the radiation disruption to generate free radical whzen exposures to UV light, which has been demonstrated, for example, P. J. Baker, A. G. Davies, M.-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅· radical. This study demonstrated cyclopentadienyl (C₅H₅) group or substituted cyclopentadienyl (C₅R₅) group has higher UV light sensitivity compared with alkyl (e.g., methyl, butyl) groups under identical conditions. This property is beneficial to decrease EUV light dose and increase resolution.

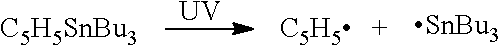

The (cyclopentadienyl)tin compounds contain tin and C—Sn bond, therefore may adsorb extreme ultraviolet light at 13.5 nm.

(Cyclopentadienyl)tin compound photoresists contain cyclopentadienyl (Cp), or substituted-cyclopentadienyl group, π bond, C—Sn bond and related interaction and may have excellent sensitivity to high energy light (e.g., EUV, or DUV) due to tin adsorption high energy EUV ray at 13.5 nm. Accordingly, the related solution compositions may have improved resolution, photosensitivity, and stability compared with organic polymer or inorganic photoresists such as metal oxides.

In some embodiments, (cyclopentadienyl)tin compound photoresists may have excellent photosensitivity to EUV radiation light due to the tin adsorption high energy EUV ray at 13.5 nm (low expose dose photoresist, e.g., <20 mJ/cm²), and the disruption of Cp-Sn bond to form free radical, tin oxide and relative products, and toughness; low or free pattern defectivity at nanoscale. Accordingly, the solution composition of (cyclopentadienyl)tin compound photoresists may have tight pitch (e.g., <10 nm), and may sustain the yield and deliver high resolution.

The (cyclopentadienyl)tin compound photoresists are soluble in appropriate organic solvents with improved uniformity for further photolithography pattern processing. The solution of (cyclopentadienyl)tin compound photoresist can be formed by dissolving in organic solvents, including but not limit to, pentane, hexane, cyclohexane, chloroform, tetrahydrofuran, dimethoxyethane, dimethylformamide, dimethyl sulfoxide, alcohols (e.g., 4-methyl-2-pentenol, ethanol, methanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. The solution composition of organotin compounds can be utilized as EUV photoresists for further processing and patterning.

The organotin photoresist composition may include 0.1 wt % to 60 wt % of the (cyclopentadienyl)tin compounds represented by chemical formulas (1)-(23), based on the total weight of the organotin photoresist composition. A person of ordinary skills in the art will recognize that the samples, concentrations, and amounts of (cyclopentadienyl)tin compounds within the explicit ranges of above are contemplated and are within the present disclosure.

In some embodiments, the (cyclopentadienyl)tin compounds represented by chemical formulas (1)-(23) may be used as precursors to prepare organotin photoresists, or organotin photoresist compositions, for example, hydrolysis with water or moisture to form organotin cluster photoresist, or reaction with oxygen sources such as oxygen, air, or hydroperoxide, or condensation reaction with organic acids (e.g., formic acid, acetic acid, citric acid, propionic acid, isovaleric acid, butyric acid, valeric acid, caproic acid, glycolic acid, lactic acid, oxalic acid, or succinic acid) to form organotin photoresists. In some embodiments, (cyclopentadienyl)tin compounds represented by chemical formulas (1)-(23) may be used as precursors for transparent conducting oxides, thermoelectric materials, or catalysts.

In the present invention, (cyclopentadienyl)tin compounds represented by chemical formulas (1)-(23) may contain four, three, two, or one cyclopentadienyl group with various functional groups, e.g., [(C₅H₄E)]₄Sn (E=O, S, Se or Te) represented by chemical formula (16).

In some embodiments, (cyclopentadienyl)tin compounds as precursors for preparation of organotin photoresists, according to embodiments of the present disclosure, may be represented by at least one of examples. Examples of specific (cyclopentadienyl)tin photoresist materials that may be used in implementations of the invention including but not limited to, oxide hydroxide, alkoxide, amide, anhydride, halide, ester, or oxo, which contain hydrolysable functional groups, such as —OR, —SR, —SeR, —TeR, —X, —N(R)₂, or —OCO.

In some embodiments, the poor stability of conventional organotin photoresists in solution after aged would lead to aggregation or precipitation with short shelf life for photolithography, which then would result in scums or defects in photolithography patterning.

In some embodiments, a blend of organotin photoresists with distinct organic ligands provides further improvement in the photolithography patterning, compare with single component organotin compound photoresist.

In some embodiments, the hydrolysable ligands of organotin photoresist precursors carry out hydrolysis with water or moisture from promoting agent to form free hydroxyl (—OH) groups, and then condensation to form organotin clusters. The aggregation of organotin clusters would bridge over proximate resist patterns and then lead to scum.

In some embodiments, a combination of a first precursor organotin compound and a second precursor (e.g., water, oxygen source, or organic acid) forms photoresist materials and deposits on the surface of substrate.

In some embodiments, the stability of (cyclopentadienyl)tin photoresists in solution can be improved by organic molecules as stabilizers. The organic molecules-stabilized (cyclopentadienyl)tin photoresists possess improved stability, solubility, uniformity, or shelf life for photolithography patterning.

In some embodiments, organic molecules stabilizers include, but not limited to, organic thiol, organic alcohol, organic amine, organic amide, organic carboxylic acid, organic phosphine, phosphine oxide, phosphonic acid, or a combination thereof.

In some embodiments, organic thiol includes, but not limited to, 1-dodecanethiol, 2-dodecanethiol, 1,12-dodecanedithiol, 1-docosanethiol, 1-decanethiol, 1-heptanethiol, 2-heptanethiol, 1-heptadecanethiol, 1-hexanethiol, 1-hexadecanethiol, 1-nonanethiol, 1-octadecanethiol, 1-octanethiol, 1-pentadecanethiol, 1-tetradecaenthiol, 1-tridecanethiol, 1-undecanethiol, 1,8-octanedithiol, 1,2-ethanedithiol, or a combination thereof.

In some embodiments, organic alcohol includes, but not limited to, 1-dodecanol, 1-octanol, 1-hexadecanol, 1-heptanol, 1-heptadecanol, 1-decanol, 1-undecanol, 1-dodecanol, 1-tridecanol, 1-tetradecaonl, 1-nonaol, 1,10-decanediol, 1,2-hexadecanediol, 1,12-dodecanediol, 1,8-octanediol, 1,11-undecanediol, 2-mercaptoethanol, or a combination thereof.

In some embodiments, organic amine includes, but not limited to, 1-heptadecyloctadecylamine, decylamine, dodecylamine, heptylamine, heptadecylamine, hexadecylamine, isotridecanamine, nonylamine, octadecylamine, octanamine, octylamine, pentadecylamine, tetradecylamine, tridecylamine, triethylamine, undecylamine, undecanamine, 1,8-diaminooctane, 1,9-diaminononane, 1,12-dodecanediamine, 1,11-undecanediamine, or a combination thereof.

In some embodiments, organic amide includes, but not limited to, decanamide, docosanamide, dodecanamide, heanoamide, heptanamide, heptadecanamide, hexadecanamide, icosanamide, nonanamide, nonadecanamide, nonaediamide, octanamide, oleamide, octadecanamide, octanediamide, pentadecanamide, tetradecanamide, tridecanamide, undecanamide, or a combination thereof.

In some embodiments, organic carboxylic acid includes, but not limited to, oleic acid, citric acid, decanoic acid, hexadecanedioic acid, lauric acid, nonanoic acid, octanoic acid, palmitic acid, suberic acid, undecanoic acid, 1,11-undecanedicarboxylic acid, thiolglycolic acid, mercaptoacetic acid, mercaptopropionic acid, or a combination thereof.

In some embodiments, organic phosphine, phosphine oxide, or phosphonic acid, include, but not limited to, trioctylphosphine, tributylphosphine, tris(dimethylamino)phosphine, tris(diethylamino)phosphine, trioctylphospine oxide, hexylphosphonic acid, octadecylphosphonic acid, 11-undecenyl phosphonic acid, or a combination thereof.

In some embodiments, organic molecules stabilizers may be adsorbed, grafted, immobilized, anchored, or coordinated on (cyclopentadienyl)tin compound photoresists as supports.

In an exemplary embodiment, the organic molecules stabilized (cyclopentadienyl)tin compound photoresist composition according to an embodiment can be prepared by the addition of organic molecular stabilizer to the solution of (cyclopentadienyl)tin compound under ambient condition. The ambient condition includes temperature range from −196 to 300° C., inert N₂ or Ar atmosphere, or air atmosphere, in organic solvent or water with various concentration. The addition of organic molecules stabilizers can be carried out during 0-24 hours after the generation of (cyclopentadienyl)tin compound photoresist solution. A person of ordinary skills in the art will recognize that the temperatures and addition rates within the explicit ranges of above are contemplated and are within the present disclosure.

In some embodiments, the solution composition of (cyclopentadienyl)tin compound photoresists containing cyclopentadienyl or substituted-cyclopentadienyl group, according to embodiments of the present disclosure, may have improved etch resistance, sensitivity and resolution, compared with related conventional organic polymer or inorganic photoresists, wherein oxygen, nitrogen, or various groups are bonded to tin metal as described above.

The solution composition of (cyclopentadienyl)tin compound photoresists can be utilized for photolithography patterning including extreme ultraviolet radiation (EUV), deep ultraviolet radiation (DUV), e-beam radiation, X-ray radiation, or ion-beam radiation for further processing and patterning.

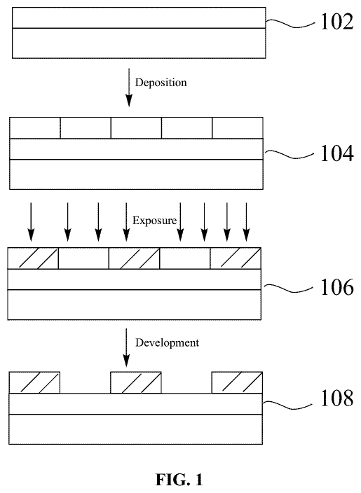

A method of forming photolithography pattern using the organotin photoresist composition is illustrated by FIG. 1.

The general photolithography process described by FIG. 1, is to deposit photoresist over a substrate 102 to form a thin photoresist layer 104; after pre-exposure baking, the formed layer is exposed to actinic radiation to form a latent image 106; after post-exposure baking, the latent is developed by the appropriate developer, such as aqueous basic/acid solutions or organic solvents, to produce the developed resist photolithography pattern 108.

In an embodiment, organotin photoresist is deposited on a surface of semiconductor substrate by wet deposition like spin-on coating, spray coating, dip coating, or knife edge coating. In another embodiment, organotin photoresist is deposited by chemical vapor deposition (CVD), atomic layer deposition (ALD), or physical vapor deposition.

In some embodiments, after exposure, the exposed and unexposed portion of organotin photoresists possess different chemical and physical properties. Organic ligands of organotin photoresists can be cleaved to form metal oxide or polynuclear oxo/hydroxo network patterns. The unexposed portion of photoresists can be removed by the developer according to different features, solubility and properties. In an embodiment, the developer is a wet developer such as organic solvent, or aqueous solution. In another embodiment, the developer is a dry developer such as Cl₂, CH₂Cl₂, BF₃, BCl₃, CF₄, CCl₄, or HBr.

In some embodiments, the developing method is sublimation or evaporation under high reduced pressure in the range of 0.0001 torr to 100 torr, and/or high temperature in the range of 20 to 300° C. A person of ordinary skills in the art will recognize that the reduced pressures and temperatures within the explicit ranges of above are contemplated and are within the present disclosure.

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), aromatic solvents (e.g., benzene, toluene, xylene), acid (e.g., formic acid, acetic acid, oxalic acid, 2-ethylhexanonic acid), and combinations thereof.

In some embodiments, the wet liquid solvent developing process is applied by dipping the exposed/unexposed substrates into a developer bath. In some embodiments, the wet solvent developing solution can be sprayed into the exposed/unexposed photoresists layer.

In addition, (cyclopentadienyl)tin compound photoresist compositions for photolithography patterning according to an embodiment is not necessarily limited to the negative tone image but may be formed to have a positive tone image.

Hereinafter, the present invention is described in more details through Examples regarding the preparation of (cyclopentadienyl)tin compounds as photoresists or precursors for organotin photoresist compositions for photolithography patterning. However, the present invention is not limited by the Examples. A person of ordinary skills in the art will recognize that the samples and solution composition components within the explicit ranges of above are contemplated and are within the present disclosure.

### EXAMPLES

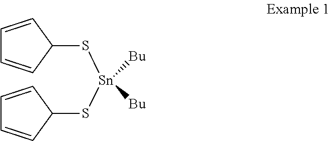

Synthesis of (C₅H₄S)₂Sn(Bu)₂. n-BuLi (2.0 mL/3.2 mmol, 1.6 M/hexane) was added to a solution of 2,4-cyclopentadienyl thiol (C₅H₄SH, 3.0 mL/3.2 mmol) in diethyl ether (50 mL) at −78° C. with vigorously stirring. After stirring for one hour, Bu₂SnCl₂ (486 mg, 1.6 mmol) in ether (10 mL) was added dropwise. Then the mixture was slowly warm to room temperature and stirred overnight. After removal of all the volatiles, the residue was extracted by toluene and filtered through a short pad of silicon. The filtrate was evaporated in vacuo to give the titled product. Yield: 416 mg, 61%. ¹H NMR (400.13 MHz, CDCl₃) δ=1.39 (bs, 18H), 3.93 (t, 2H), 6.42 (m, 4H), 6.53 (m, 4H). EI-MS (70 eV): m/z 427 (M⁺).

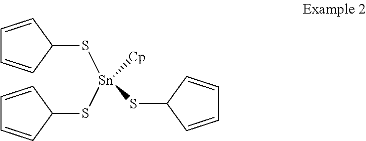

Synthesis of (C₅H₄S)₃Sn(Cp). At −78° C., n-BuLi (2.1 mL/3.3 mmol, 1.6 M/hexane) was added to a solution of 2,4-cyclopentadienyl thiol (C₅H₄SH) (0.29 mL, 3.3 mmol) in diether ether (50 mL). The mixture was stirred for hour. Then a solution of (cyclopentadienyl)tin trichloride (CpSnCl₃, 310 mg, 1.06 mmol) in diethyl ether (20 mL) was added dropwise with vigorously stirring. After addition, the mixture was stirred for further hour and was slowly warmed to r.t. with stirring overnight. After removal of all the volatiles, the residue was extracted by toluene and filtered through short pad of silicon. The filtrate was then evaporated in vacuo to give the titled product. Yield: 317 mg, 63%. ¹H NMR (400.13 MHz, CDCl₃) δ=3.91 (t, 3H), 5.90 (m, 5H), 6.36 (m, 6H), 6.50 (m, 6H). EI-MS (70 eV): m/z 475 (M⁺). Elemental analysis of C₂₀H₂₀S₃Sn (475.10), anal. calculated C: 50.56%; H: 4.21; and found C: 50.69; H, 4.66.

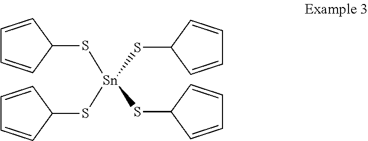

Synthesis of (C₅H₄S)₄Sn. At −78° C., n-BuLi (9.4 mL/15.0 mmol, 1.6 M/hexane) was added to a solution of 2,4-cyclopentadienyl thiol (C₅H₄SH) (1.3 mL, 15.0 mmol) at −78° C. with vigorously stirring. After stirring for one hour, a solution of SnCl₄ (0.45 mL, 3.8 mmol) in hexane (10 mL) was added dropwise in one hour with vigorously stirring (Caution: SnCl₄ is extremely hydrolytic when exposure to air or water and releasing HCl gaseous !!!). Then the mixture was slowly warm to room temperature and stirred overnight. After removal of all the volatiles, the residue was extracted by toluene/THF and filtered through Celite. The filtrate was evaporated in vacuo to give the titled product. Yield: 0.96 g, 50%. ¹H NMR (400.13 MHz, CDCl₃) δ=3.96 (t, 4H), 6.46 (m, 8H), 6.55 (m, 8H). EI-MS (70 eV): m/z 507 (M⁺).

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the sprit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin photoresist composition for photolithography patterning, comprising:
a (cyclopentadienyl)tin compound, a solvent, and/or an additive;
wherein (cyclopentadienyl)tin compound is one or more selected from chemical formulas (1)-(23) as below: 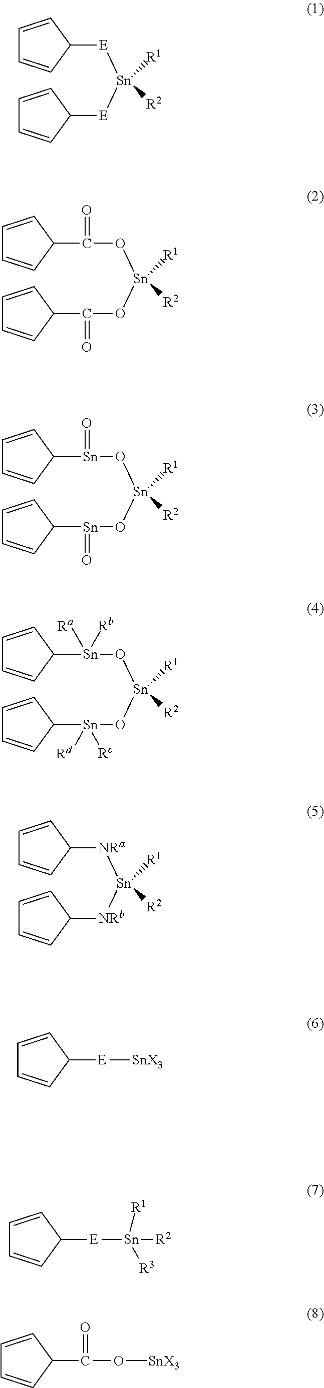 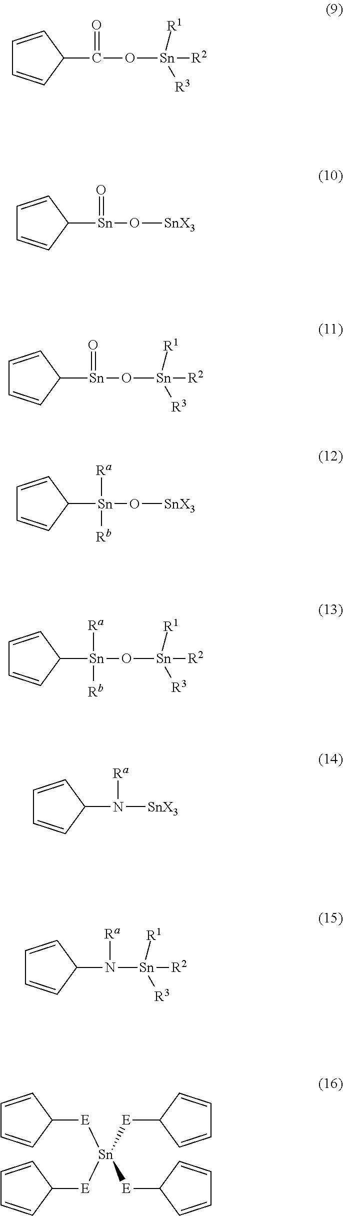 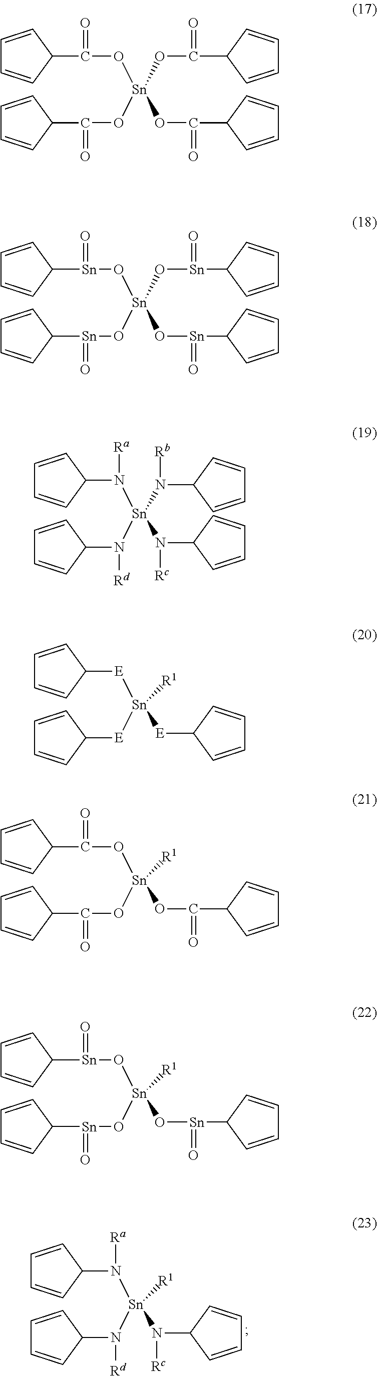
wherein R¹, R², R³ are independently —R′, -ER′, —N(R′)₂, —O—(C═O)—R′, —(C═O)—R′, —N(R′)—(C═O)—R′, or —(C═O)—N(R′)₂ group, wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
wherein R^{a}, R^{b}, R^{c}, R^{d} are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te, X=F, Cl, Br, or I.

2. The organotin photoresist composition of claim 1, wherein cyclopentadienyl group includes cyclopentadienyl C₅H₅ group, or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

3. The organotin photoresist composition of claim 1, wherein cyclopentadienyl group comprises hapticity of η¹, η², η³, η⁴, η⁵ of isomers.

4. The organotin photoresist composition of claim 1, wherein cyclopentadienyl comprises 1,3-cyclopentadienyl, 2,4-cyclopentadienyl C₅H₅ group, or substituted 1,3-cyclopentadienyl, 2,4-cyclopentadienyl C₅H₄R, C₅H₃R₂, C₅H₂R₃, C₅HR₄, or C₅R₅ group.

5. The organotin photoresist composition of claim 2, wherein R=H, a methyl, ethyl, propyl, n-butyl, t-butyl, or cyclohexyl group.

6. The organotin photoresist composition of claim 1, wherein cycloalkenyl group comprises substituted or unsubstituted C4 to C8 cyclic aliphatic unsaturated organic groups including at least one double bond.

7. The organotin photoresist composition of claim 1, wherein the additive comprises organic thiol, organic alcohol, organic amine, organic amide, organic carboxylic acid, organic phosphine, organic phosphine oxide, or organic phosphonic acid.

8. The organotin photoresist composition of claim 1, wherein photolithography patterning includes extreme ultraviolet radiation, deep ultraviolet radiation, e-beam radiation, X-ray radiation, or ion-beam radiation.

9. The organotin photoresist composition of claim 1, wherein R′ is a methyl, ethyl, propyl, n-butyl, t-butyl, cyclohexyl, or cyclopentadienyl group.

10. The organotin photoresist composition of claim 1, wherein R^{a}, R^{b}, R^{c}, R^{d} are each independently a methyl, ethyl, propyl, n-butyl, t-butyl, or cyclopentadienyl group.

11. The organotin photoresist composition of claim 1, wherein (cyclopentadienyl)tin compounds represented by chemical formulas (1)-(23) may also be used as precursors for the preparation of organotin photoresist, or organotin photoresist composition.

12. A method for photolithography patterning, comprising:
depositing an organotin photoresist composition over a substrate;
wherein the organotin photoresist comprises a (cyclopentadienyl)tin compound,
wherein the (cyclopentadienyl)tin compound is one or more selected from chemical formulas (1)-(23) as below: 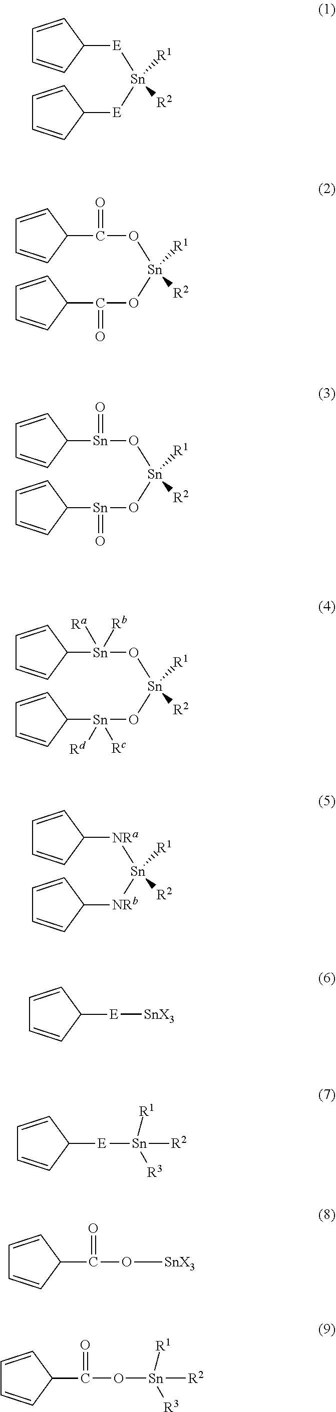 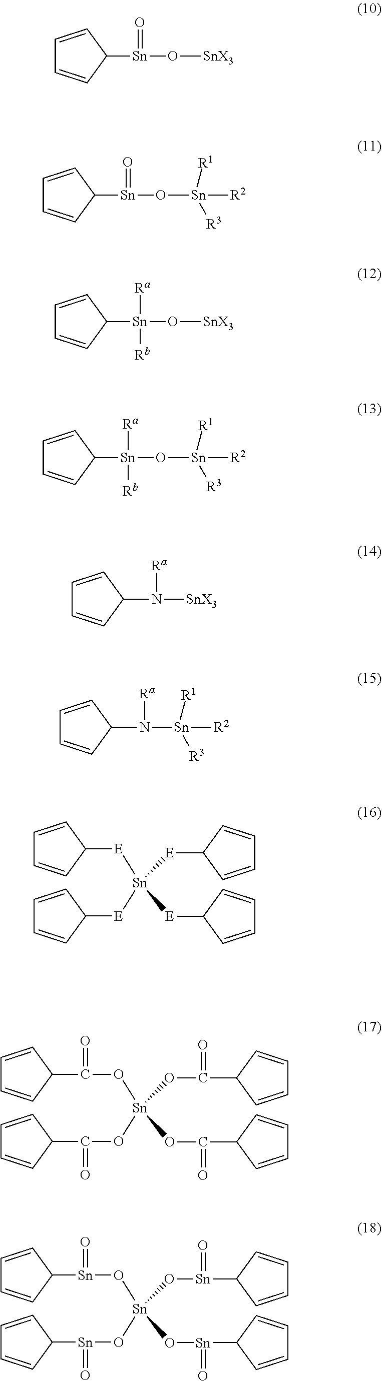 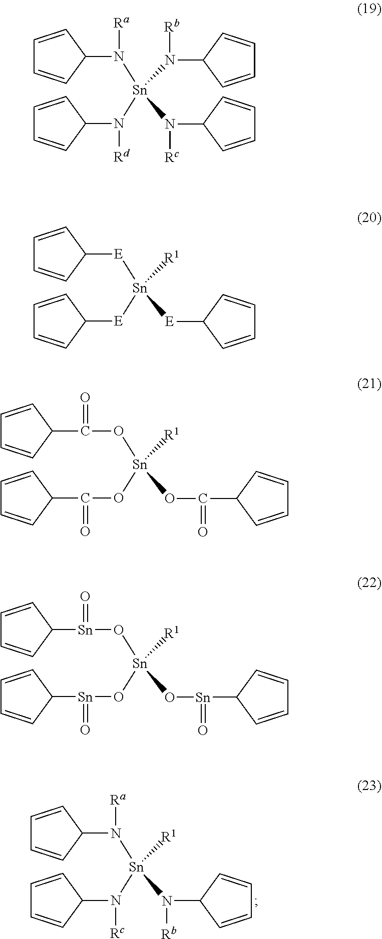
wherein R¹, R², R³ are independently —R′, -ER′, —N(R′)₂, —O—(C═O)—R′, —(C═O)—R′, —N(R′)—(C═O)—R′, or —(C═O)—N(R′)₂ group, wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
wherein R^{a}, R^{b}, R^{c}, R^{d} are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te, X=F, Cl, Br, or I;
exposing the organotin photoresist layer to actinic radiation to form a latent pattern; and
developing the latent pattern by applying a developer to remove the unexposed or exposed portion of photoresists to form a photolithography pattern.

13. The method of claim 12, wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

14. The method of claim 12, wherein cyclopentadienyl group is 2,4-cyclopentadienyl group, or substituted 2,4-cyclopentadienyl group.

15. The method of claim 12, wherein R′ is H, a methyl, ethyl, propyl, n-butyl, t-butyl, phenyl, benzyl, or cyclopentadienyl group.

16. The method of claim 12, wherein R^{a}, R^{b}, R^{c}, R^{d} are each independently a methyl, ethyl, propyl, n-butyl, t-butyl, cyclopentadienyl, phenyl, or benzyl group, E=O, or S; X=Cl.

17. An organotin compound bearing cyclopentadienyl group represented by chemical formulas as below: 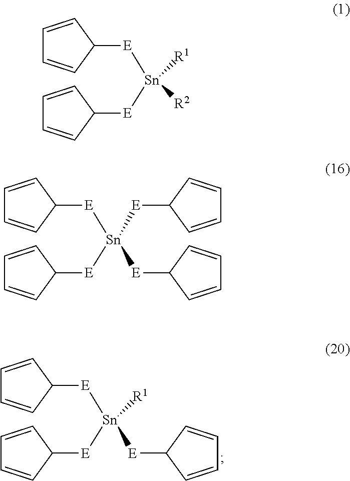
wherein R¹, R² are independently an alkyl, alkenyl, alkynyl, cycloalkyl, or cycloalkenyl group with 1 to 20 carbon atoms, or an aryl group with 6-20 carbon atoms; E=O, S, Se, or Te.

18. The organotin compound of claim 17, wherein R¹, R² are cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴ or η⁵ of isomers, wherein R is H, a substituted or unsubstituted alkyl, alkenyl, alkynyl, cycloalkyl, or cycloalkenyl group with 1 to 20 carbon atoms; or a substituted or unsubstituted aryl group with 6-20 carbon atoms, or an amino, cyano, ether, ester, halide, nitro, silyl, thiol, or carbonyl group.
